(19) United States
(12) Patent Application Publication
(10) Pub. No.: US 2004/0005754 A1
(43) Pub. Date: Jan. 8, 2004

(54) Method for attaching an integrated circuit on a silicon chip to a smart label

(75) Inventor: Samuli Stromberg, Tampere (FI)

Correspondence Address: FITCH EVEN TABIN AND FLANNERY, 120 SOUTH LA SALLE STREET, SUITE 1600, CHICAGO, IL, 60603-3406, US

(73) Assignee: Rafsec Oy

(21) Appl. No.: 10/438,589

(22) Filed: May 15, 2003

Related U.S. Application Data
(63) Continuation of application No. PCT/FI01/00961, filed on Nov. 5, 2001.

(30) Foreign Application Priority Data
Nov. 20, 2000 (FI) 20002543

(51) Int. Cl. H01L 21/8238

(52) U.S. Cl. 438/222

(57) ABSTRACT

A method for manufacturing a smart label web comprises smart labels placed one after and/or next to each other and comprising a circuitry pattern and an intergrated circuit on a chip therein. In the method, an electric contact is formed between the integrated circuit on the chip and the circuitry pattern on the smart label of the smart label web. The integrated circuit on the chip is attached to the circuitry of the smart label by means of a thermoplastic film on the surface of the chip.

The present invention relates to a method for pretreatment of a silicon wafer, and a method for attaching an integrated circuit on a silicon chip to a smart label.

A method is known from the publication U.S. Pat. No. 5,810,959, in which a substrate and a silicon chip are attached by means of an anisotropic conductive thermosetting adhesive by using heat and pressure.

Publication U.S. Pat. No. 5,918,113 discloses a method, in which an anisotropic conductive adhesive is applied onto a circuit board, the adhesive containing a thermoplastic or thermosetting resin and conductive powder dispersed therein. The adhesive layer is softened and a semiconductor chip is adhered to it by means of heat and pressure.

From the publication U.S. Pat. No. 5,918,363, a method is known in which integrated circuits formed on a wafer are tested to determine whether they are functional, an underfill is applied on the functional integrated circuits, and the chips are separated from each other. The underfill can contain a thermoplastic substance. After this, the silicon chips are connected to their location of use in such a way that the underfill is spread around the electric connections.

From the publication U.S. Pat. No. 5,936,847, an electronic circuit is known in which there is a non-conductive polymer layer forming the underfill between the substrate and the chip. The polymer layer is provided with openings for electrical contacts. The substrate is also provided with openings, through which a conductive polymer is sprayed to form an electrical contact between the substrate and the chip.

The publication U.S. Pat. No. 6,040,630 discloses a connection for a chip which can also be released, if necessary. On a substrate having a circuitry pattern formed on the substrate, a thermoplastic film is positioned, having vias that expose the bumps of the chip. The thermoplastic film forms an underfill for the chip, and when the film is heated, it connects the chip and the circuitry pattern.

A method is known from the publication U.S. Pat. No. 6,077,382 in which an anisotropic conductive thermosetting adhesive is placed on a circuit board, and the circuit board is heated to a temperature which is lower than the setting temperature of the adhesive. A semiconductor chip is placed in its position and adhered by means of heat and pressure.

A problem in the process of manufacture of a smart label web is how to attach the integrated circuit on the chip to the circuitry pattern. According to prior art, the attachment can be made so that the solder bumps on the chip are attached to the circuitry pattern of the smart label and a so-called underfill is formed between the smart label and the chip by means of capillary forces, to level out tensions caused by thermal expansion between the chip and the adhering substrate. The underfill also prevents the movement of the solder joint and the development of fractures in the solder joint. By adding filler particles in the underfill, the underfill can be stiffened to prevent bending of the joint. There are several types of underfills, and the used technique is also dependent on the type of the underfill. Using an anisotropic conductive thermosetting underfill, the underfill can also be formed in such a way that film pieces of suitable size are detached from a carrier web and placed on the smart label web, after which the chips provided with bumps are placed onto the underfill and the underfill is cured.

The underfill is a problematic point in the process, because it requires a separate process step that takes a relatively long time due to the curing time required by the underfills, typically several minutes. In the process, the curing of the adhesive may be required under pressure, wherein the curing must be performed by installed thermal resistors. The production line is thus expensive and inflexible.

By means of the methods according to the invention it is possible to avoid the above-mentioned problems. The method of the invention for manufacture of a smart label web is characterized in tha the integrated circuit on the chip is attached to the circuitry pattern of the smart label by means of a thermoplastic film on the surface of the chip. The method of the invention for pretreatment of a silicon wafer is characterized in that, before the separation of the wafer into single chips, a thermoplastic film is adhered to the surface of the wafer. The method of the invention, in which the thermoplastic film is readily adhered to the surface of the chip, provides the manufacture of a smart label web with the following advantages:

there is no need for a separate method step for attaching an anisotropic conductive film piece to the smart label, nor for time-consuming hardening by heat, wherein the production line becomes simpler, more reliable and less expensive than production lines of prior art,

it is possible to improve the capacity of smart label production lines,

it is possible to have shorter processing times,

it is possible to use materials with lower temperature resistance in the smart label web, because the processing temperatures of thermoplastic materials are typically about 40° C. lower and the processing times are less than a third of corresponding thermosetting materials, and

it is possible to integrate the steps of the process better than before.

In this Finnish application, the English terms corresponding to the Finnish terms are often included in parenthesis, because the English terms are regularly used by persons skilled in the art.

In the present application, smart labels refer to labels comprising an RF-ID circuit (identification) or an RF-EAS circuit (electronic article surveillance). A smart label web consists of a sequence of successive and/or adjacent smart labels. The smart label can be manufactured by pressing a circuitry pattern with an electroconductive printing ink on a film, by etching the circuitry pattern on a metal film, by punching the circuitry pattern from a metal film, or by winding the circuit pattern of for example a copper wire. The electrically operating RFID (radio frequency identification) circuit of the smart label is a simple electric oscillating circuit (RCL circuit) operating at a defined frequency. The circuit consists of a coil, a capacitor and an integrated circuit on a chip. The integrated circuit comprises an escort memory and an RF part which is arranged to communicate with a reader device. Also the capacitor of the RCL circuit can be integrated on the chip. The smart label web is of a material that is flexible but still has a suitable rigidity, such as polycarbonate, polyolefine, polyester, polyethylene terephtalate (PET), polyvinyl chloride (PVC), or acrylonitrile/butadiene styrene copolymer (ABS).

The wafer is normally supplied for use in attaching processes so that the chips are separated from each other, on top of a carrying film carried by a frame. The single chips are detached in the process by pushing the chip mechanically from underneath the carrying film and by gripping it from the opposite side with a turning tool utilizing an underpressure suction.

In the method of the invention for pretreatment of a silicon wafer, the wafer is pretreated so that a thermoplastic film is attached to the surface of the wafer which is provided with bumps and checked for functionality, before the separation of the wafer into single chips. Thermoplastic films refer to films whose surface can be made adherent to another surface by the effect of heat, but which are substantially non-adherent in room temperature. Thermoplastic films can also be heated several times without substantially affecting the adherence. Substantially the same process conditions can be used for both anisotropic conducting and non-conducting thermoplastic films. As an example to be mentioned, thermoplastic films include anisotropic conductive films 8773 and 8783 (Z-Axis Adhesive Films 8773 and 8783) by 3M. The film contains conductive particles in such a way that it is electroconductive in the thickness direction of the film only, that is, there is no conductivity in the direction of the plane of the film. The thermoplastic film can be made fluid by means of heat and pressure. When cooled, the thermoplastic film is crystallized and gives the bond mechanical strength. Thermosetting will not be necessary. The thermoplastic film can be of e.g. polyester or polyether amide. The conductive particles, having a size of typically 7 to 50 μm, can be e.g. glass particles coated with silver. The thickness of the thermoplastic film is typically 20 to 70 μm. The thermoplastic film is normally formed on the surface of a release paper or the like. The release paper can be released from the film in connection with heating of the film. The process temperatures presented in the application, typical for thermoplastic films, are the same both for the bonding of the film on the wafer and for the bonding of the film-coated chip to the smart label of the smart label web, because it is a question of temperatures related to the properties of these materials.

In the method of the invention for bonding a chip to a smart label in a smart label web, the chip and the circuitry pattern are connected to each other by means of a thermoplastic film attached to the chip, wherein an electric contact is formed between the chip and the circuitry pattern. The thermoplastic film can be an anisotropic electroconductive thermoplastic film (AFC) or a non-conductive film (NCF). When a thermoplastic film is used, there is no need for an underfill, because the thermoplastic film forms a sufficiently flexible backing for the chip. When a non-conductive thermoplastic film is used, the reliability of the electric contact is slightly lower than in the case of an anisotropic conductive film, but it is still sufficient. It is also possible to introduce the thermoplastic non-conductive film in the full width of the web on top of the smart label web and to connect the chips to the contact area.

From the wafer that is separated into single chips after the attachment of the thermoplastic film, chips are picked up in a continuous manner so that the chips are placed onto the smart label web in a precisely focused manner. When the chip is placed onto the web, the web is heated on the opposite side so that the chip is tacked lightly to the web before making the final bond. After this, the final bond of the chip can be made by means of heat and pressure for example in a nip formed by two rolls, where at least one of the contact surfaces forming the nip is heated and at least one is resilient. In said nip, it is possible either to laminate, on both sides of the smart label web, the other layers simultaneously onto the structure, or to leave out the layers and to use the nip to achieve a connection only. At the same time, it is possible to level out the profile of the smart label by discharging some of thermoplastic film in fluid form from the top of the chip. It is also possible to start cross-linking of an adhesive layer upon combining several layers simultaneously, to provide a more reliable lamination result or a more rigid structure.

In addition to the above-mentioned nip, a nip can also be formed between a shoe roll and its counter roll. The thermoplastic film can also be heated by microwaves, wherein the film can be heated selectively, simultaneously applying pressure on the bond (materials blended with selective additives are heated in a microwave field).

In the following, the invention will be described with reference to the appended drawings, in which

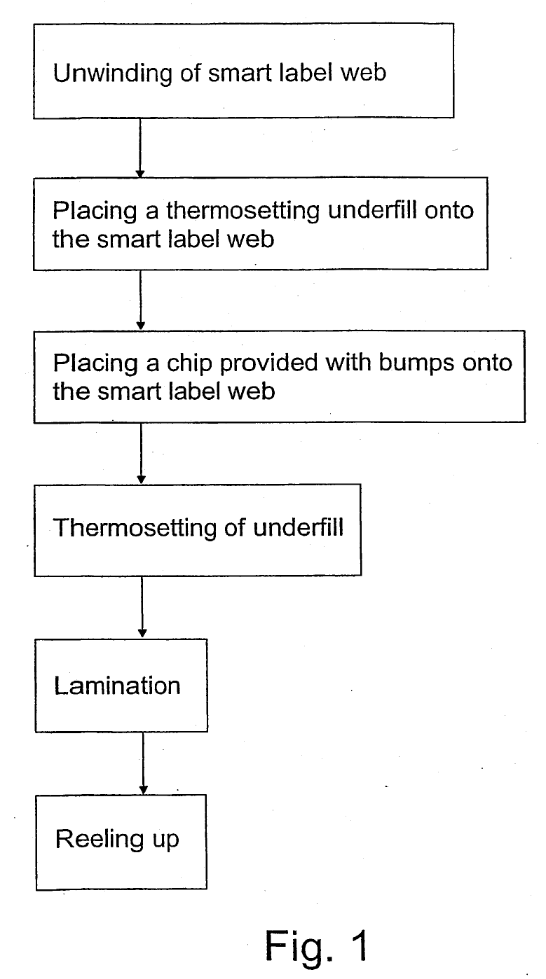

FIG. 1 shows a process chart for attaching a chip to a smart label by a method of prior art,

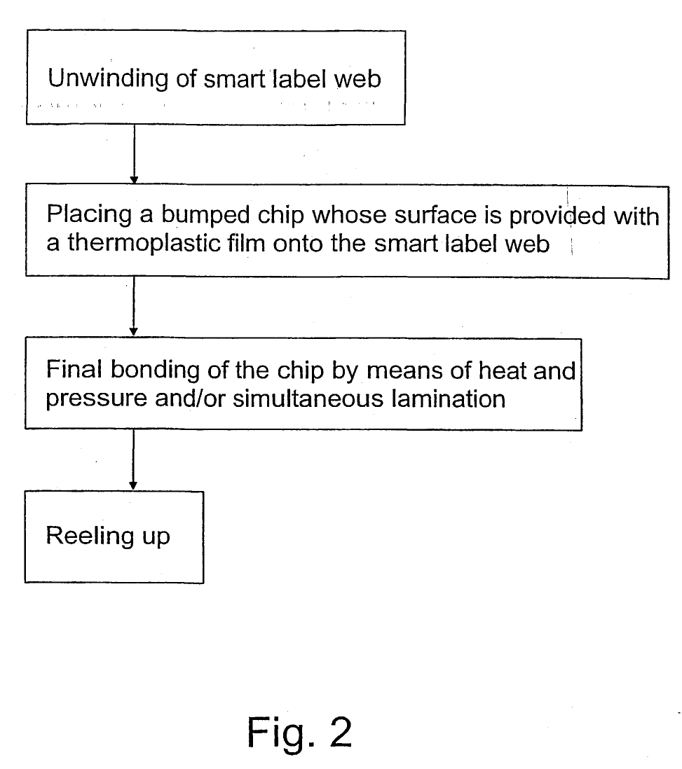

FIG. 2 shows, in a process chart, the method of the invention for attaching a chip onto a smart label,

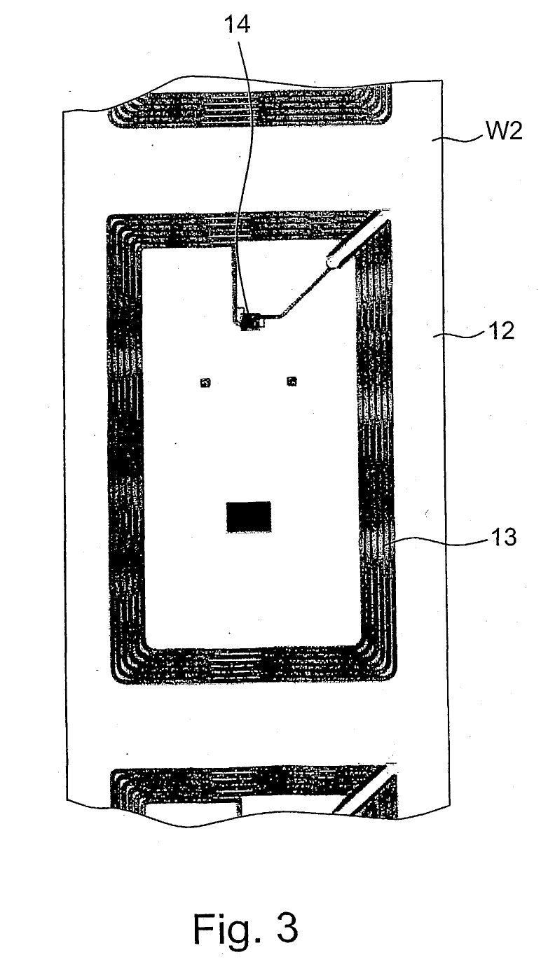

FIG. 3 shows a smart label web in a top view, and

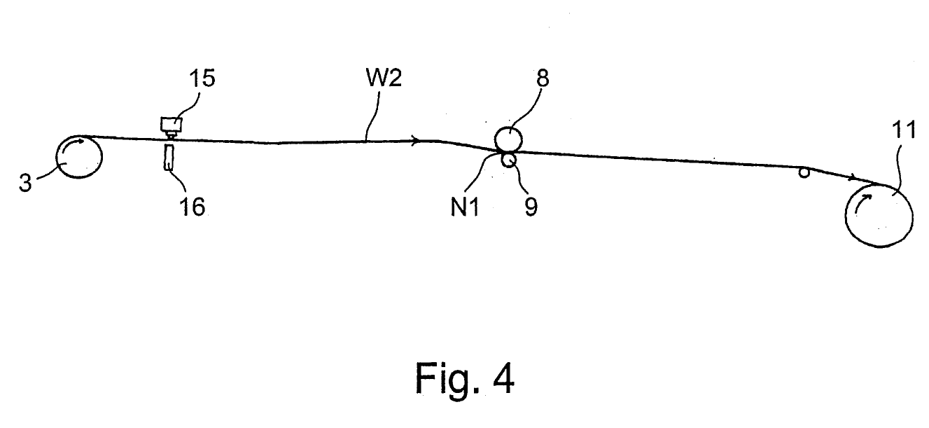

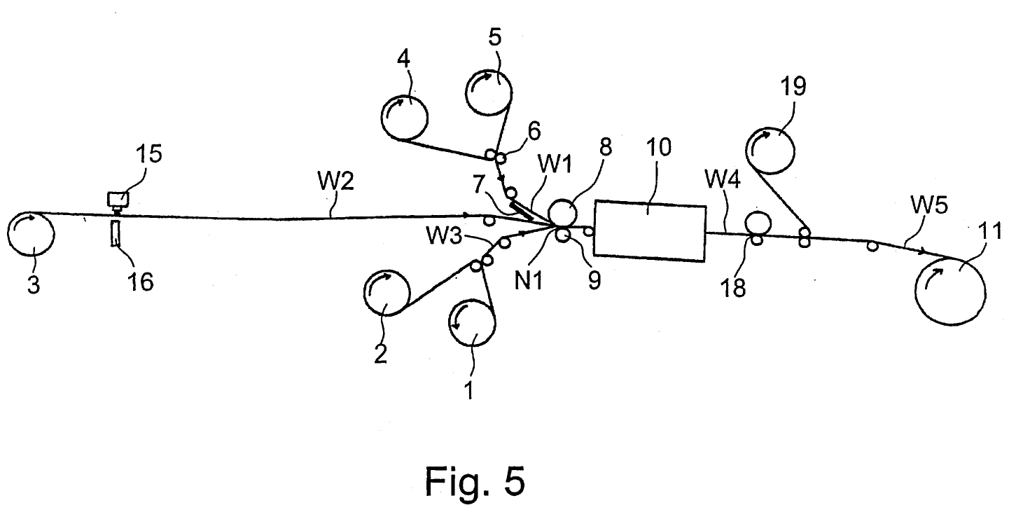

FIGS. 4 and 5 show side views of some production lines according to the invention, whereby a chip can be attached to smart labels of a smart label web.

FIG. 1 shows a prior art method for forming an anisotropic thermosetting film attachment. A smart label web containing smart labels one after another and possibly also adjacent to each other, is unwound from a reel. From another reel, a carrier web is unwound that contains pieces of a thermosetting film with the required size on its surface. A piece of the thermosetting anisotropic film is detached from the carrier web and placed on the smart label at the point where the chip provided with bumps will be attached in the next step of the process. The thermosetting anisotropic conductive underfill is cured, and the smart label web is then possibly laminated with the other layers of the web. Finally, the smart label web and the other layers possibly attached to it are reeled up.

FIG. 2 shows a new method according to the invention, in which a chip is attached to a smart label web by means of a thermoplastic, anisotropic conductive film or a thermoplastic non-conductive film. The smart label web is unwound, and a chip is placed onto the circuitry pattern of the smart label, a thermoplastic film being readily attached to the other surface of the chip. On the opposite side of the web, the smart label web is heated to such a temperature that the film on the surface of the web can be attached to the web, at a desired location. After this, the final bond of the chip and the smart label is made by means of heat and pressure, for example in a nip formed by two rolls, longer than a nip formed by hard rolls. Thus, at least one of the two contact surfaces forming the nip is heated. Simultaneously with the final bonding of the chip, it is possible to laminate the smart label web with the other web layers. The lamination process can also be separate, wherein the hot and long nip is only used to perform the final bonding of the chip to the smart label web. Finally, the smart label web and the other layers possibly attached to it are reeled up.

FIG. 3 shows a smart label web W2 in a top view, including a single smart label 12 comprising a circuitry pattern 13 and an integrated circuit 14 therein. The smart label 12 can be manufactured by pressing the circuitry pattern on a film with an electroconductive printing ink, by etching the circuitry pattern on a metal film, by punching the circuitry pattern from a metal film, or by winding the circuitry pattern of e.g. copper wire. The circuitry pattern is provided with an identification circuit, such as a radio frequency identification (RFID) circuit. The identification circuit is a simple electric oscillating circuit (RCL circuit) tuned to operate at a defined frequency. The circuit consists of a coil, a capacitor and a circuit integrated on a chip, consisting of an escort memory and an RF part for communication with a reader device. The capacitor of the RCL circuit can also be integrated on the chip.

In FIG. 4, the smart label web W2 containing smart labels 12 one after another on a carrier web, is unwound from a reel 3. The carrier web may also contain several smart labels side by side. The material of the smart label web W2, onto whose surface the circuitry pattern is formed and the integrated circuit is attached, is preferably a plastic film with a suitable rigidity.

From a wafer which is provided with bumps, whose surface is impregnated with a thermoplastic film and which is separated into single chips after the impregnation with the film, a single chip is picked up and placed onto the circuitry pattern 13 of the smart label in a focused manner by means of an insertion tool 15. At the same time, the smart label is heated with a heater 16 at the location where the chip is placed on the opposite side of the smart label. The heating of the smart label will make the thermoplastic film on the surface of the chip adhere to the circuitry pattern. The thermoplastic film is preferably heated to a temperature of 80 to 105° C.

Further, the final bond between the integrated circuit on the chip and the circuitry pattern is made on application of heat. Thus, the thermoplastic film is preferably heated to a temperature of 140 to 150° C. The smart label web can be led to a nip where at least one of the two contact surfaces is heated. The nip is preferably a nip longer than a nip formed by hard rolls. The nip can be for example a nip N1 formed by a thermoroll and a resilient roll, wherein the pressure per unit area is lower than in a corresponding hard nip. One of the contact surfaces forming the nip can also be a shoe roll. It is also possible that the heating takes place before the nip, wherein the thermoplastic film between the circuitry pattern of the smart label and the integrated circuit on the chip is heated for example by microwaves. The thermoplastic film is thus blended with additives which are heated by microwaves. After the heating by microwaves, the smart label web, onto which the integrated circuit on the chip is placed, is introduced to a process step which exerts pressure on the joint surface. It is also possible that the heating by microwaves and the exertion of pressure on the joint surface take place simultaneously. The force which is exerted to the joint is preferably 200 to 800 g per joint, irrespective of which of the above-mentioned methods is used for making the final bond of the chip. After the chip has been attached to the smart label web W2, the web is reeled up on a roll 11.

FIG. 5 shows a method in which the circuit integrated on the chip is attached to the circuitry pattern of the smart label as presented in connection with the description of FIG. 4. It is thus possible that in the same nip where the final bond of the integrated circuit is made, the smart label web W2, a liner web W1 and a back web W3 are also combined. Thus, the continuous web comprising the liner web W1 is unwound from the reel 5. From the reverse side of the liner web W1, the release web of the liner web is released and, after the releasing, it is reeled up on a roll 4. On the side where the release web was released, the liner web W1 is impregnated with an adhesive whose adhesion can be improved by heating it with a heater 7 which can be for example an infrared heater. The material of the liner web WI is preferably a polyolefine film, such as a polypropylene or polyethylene film.

The continuous web comprising the back web W3 is unwound from the reel 1. From the reverse side of the back web W3, the release web of the back web is released and, after the releasing, it is reeled up on a roll 2. On the side where the release web was released, the back web W3 is provided with an adhesive. The adhesive can be for example a pressure-sensitive adhesive which can be made to adhere to another surface by pressing it against the other surface.

The liner web W1, the smart label web W2 and the back web W3 are bound to each other in a nip N1 formed by rolls 8 and 9, which is a resilient, long nip. The nip N1 is followed by a radiator device 10 to which the blank of the smart label inlet web W4 is led, if the surface of any web is provided with an adhesive to be cured by radiation. The radiator device 10 can produce ultraviolet radiation or electron beams. The blank of the smart label inlet web W4 is further introduced to a punching unit 18 in which the liner web W1 and the smart web W₁2 are punched at a suitable location so that the surface of the back web W3 is provided with a sequence of smart labels 12 of a fixed size and protective surface films on top of them. After the punching, excess parts of the liner web W1 and the smart label web W3 are left outside the smart label 12 and the surface film and are removed by reeling up the excess material on a reel 19. The ready made web W5 is reeled up on a reel 11.

The process according to FIG. 5 can be modified according to the need. It can be supplemented with new parts or something can be left out. In some processes, for example the treatment with an infrared heater, the curing of the adhesive in a radiator device, the punching to a suitable size, or the removal of excess material may be unnecessary steps in the process. When several webs are combined in the same nip, their number is not limited but it may vary according to the case.

The invention is not restricted to the description above, but the invention may vary within the scope of the claims. The main idea in the invention is that by attaching the thermoplastic film readily onto the surface of the integrated circuit on the chip, it is possible to make the final bond between the chip and the smart label in a simple and reliable manner.

1. A method for manufacturing a smart label web comprising smart labels one after another and/or side by side, which smart labels include a circuitry pattern and an integrated circuit on a chip attached to the smart label, the method comprising forming an electric contact between the integrated circuit on the chip and the circuitry pattern on the smart label of the smart label web, wherein the integrated circuit on the chip is attached to the circuitry pattern of the smart label by a thermoplastic film on a surface of the chip.

2. The method according to claim 1, wherein the integrated circuit on the chip is attached to the circuitry pattern of the smart label by a thermoplastic anisotropic conductive film on the surface of the chip.

3. The method according to claim 1, wherein the integrated circuit on the chip is attached to the circuitry pattern of the smart label by a thermoplastic non-conductive film on the surface of the chip.

4. The method according to claim 1, wherein the smart label is heated at the location of the bond of the chip in such a way that the thermoplastic film can be made to adhere to the circuitry pattern of the smart label.

5. The method to claims 1, 2, 3 or 4, wherein the smart label, to which the integrated circuit on the chip is attached, is subjected to a treatment by simultaneous or successive steps of heat and pressure.

6. The method according to claim 5, wherein the smart label web is attached to the other web layers simultaneously when it is treated by heat and pressure.

7. The method according to claim 5, wherein the smart label web is treated by heat and pressure in a nip which is formed by contact surfaces of which at least one is resilient and at least one is heated.

8. The method according to claim 5, wherein the smart label web is treated by heat and pressure in such a way that the thermoplastic film is first heated by microwaves and the smart label web is then subjected to pressure.

9. A method for pretreatment of silicon wafer, comprising:
providing integrated circuitry with bumps;
checking the integrated circuits for functionality;
attaching a thermoplastic film to a surface of a wafer; and
separating the integrated circuits into single chips.

10. The method according to claim 9, wherein the thermoplastic film and/or wafer is heated, the heating effective for causing the thermoplastic film to adhere to the surface of the wafer.

11. The method according to claim 9 or 10, wherein a release paper or the like is released from the thermoplastic film.

12. The device according to claim 11, wherein the wafer is separated into single chips.
